(19) United States
(12) Patent Application Publication
(10) Pub. No.: US 2011/0263089 A1
(43) Pub. Date: Oct. 27, 2011

(54) METHOD FOR FABRICATING SEMICONDUCTOR DEVICE

(75) Inventor: Jeong Hoon PARK, Yongin-si (KR)

(73) Assignee: HYNIX SEMICONDUCTOR INC., Icheon-si (KR)

(21) Appl. No.: 13/094,211

(22) Filed: Apr. 26, 2011

(30) Foreign Application Priority Data
Apr. 27, 2010 (KR) 10-2010-0038887

(51) Int. Cl. H01L 21/336

(52) U.S. Cl. 438/270; 257/E21.41

(57) ABSTRACT

A semiconductor device is fabricated by forming a first gate conductive layer in a peripheral circuit region of a semiconductor substrate including a cell region and the peripheral circuit region; forming a buried-type gate in the cell region; and forming a bit line contact and a bit line conductive layer in the cell region and a second gate conductive layer in the peripheral circuit region. This minimizes a process for opening the cell region and the peripheral circuit region, thereby minimizing defects that can be generated from a boundary between the cell region and the peripheral circuit region. As a result, the manufacturing cost of devices may be reduced.

### CROSS-REFERENCE TO RELATED APPLICATION

The priority of Korean patent application No. 10-2010-0038887 filed on Apr. 27, 2010, the disclosure of which is hereby incorporated in its entirety by reference, is claimed.

### BACKGROUND OF THE INVENTION

An embodiment of the present invention relates generally to a method for fabricating a semiconductor device, and more particularly to a method for fabricating a semiconductor device comprising a buried-type gate.

A dynamic random access memory (DRAM) device includes a plurality of unit cells each having a capacitor and a transistor. The capacitor is used to temporarily store data, and the transistor is used to transfer data between a bit line and the capacitor in response to a control signal (word line). The data transfer occurs by using the semiconductor property of changing electrical conductivity depending on the external conditions. A transistor has three regions of gate, source, and drain. Electric charges move between the source and drain based on the control signal at the transistor gate. The moving electric charges between the source and drain flow through a channel region having the semiconductor property.

In a conventional method for manufacturing a transistor, a gate is formed in a semiconductor substrate, and source and drain are formed by doping impurities into the semiconductor substrate on the sides of the gate. The channel region of a transistor is defined under the gate between the source and drain of the transistor. The transistor having a horizontal channel region occupies a predetermined area of a semiconductor substrate. A large number of transistors are needed in a complicated or highly integrated semiconductor memory device, which often makes it difficult to reduce the total area of the semiconductor memory device.

Reducing the total area of a semiconductor memory device leads to increased number of semiconductor memory devices manufactured per wafer, thereby improving productivity. On conventional method proposes to replace a conventional planar gate having a horizontal channel region with a recess gate in which a recess is formed in a substrate and a channel region along a curved surface of the recess by forming a gate in the recess. A buried gate concept has also been studied to reduce a parasitic capacitance of a bit line by burying the entire gate within the recess.

A buried gate is formed by burying the whole gate below the surface of the semiconductor substrate while securing the length and width of the channel. When compared to a recess gate, the buried gate can reduce the parasitic capacitance generated between the gate (i.e., connected to a word line) and the bit line by 50%.

However, when forming a buried gate in the structure including the cell region and peripheral circuit region, the height of the cell region remains corresponding to the height where a gate of the peripheral circuit region is formed. As a result, it matters how this height difference is used. In order to use the height difference in the conventional art, (i) a cell region space is prepared corresponding to the height of the gate of the peripheral circuit region, or (ii) the bit line of the cell region is formed together when the gate of the peripheral circuit region is formed.

However, when a space of the cell region is prepared, the difficulty of the process for forming a bit line may be increased because a height of a storage node contact plug in the cell region is increased and a storage node contact hole is deeply formed. When the gate of the peripheral circuit region and the bit line of the cell region are formed together, a barrier metal layer is formed together because an electrode of the bit line of the cell region shares a gate electrode material of the peripheral circuit region. As a result, while the height is increased, the parasitic capacitance in the cell region is increased so that it is impossible to form a buried gate.

### BRIEF SUMMARY OF THE INVENTION

Various embodiments of the invention are directed to a method for fabricating a semiconductor device comprising a buried-type gate. The method minimizes a process for opening the cell region and the peripheral region, thereby minimizing defects that can be generated from a boundary between the cell region and the peripheral circuit region. As a result, the manufacturing cost of devices may be reduced.

According to an embodiment of the present invention, a method for fabricating a semiconductor device comprises: forming a first gate conductive layer in a peripheral circuit region of a semiconductor substrate including a cell region and the peripheral circuit region; forming a buried-type gate in the cell region; and forming a bit line contact and a bit line conductive layer in the cell region and a second gate conductive layer in the peripheral circuit region.

The step of forming a bit line contact and a bit line conductive layer in the cell region is simultaneously performed with the step of forming a second gate conductive layer in the peripheral circuit region.

Before forming a first gate conductive layer, the method further comprises: forming a mask that exposes a device isolation region in the cell region and the peripheral circuit region of the semiconductor substrate; etching the semiconductor substrate with the mask to form a trench; burying a device isolation material in the trench; and removing the mask.

The step of forming a buried type gate in the cell region includes: depositing a hard mask oxide film in the cell region; etching an active region and a device isolation film with the hard mask oxide film as a mask to form a recess; burying a gate electrode in a lower portion of the recess; and burying a capping nitride film over the gate electrode in the recess. As a result, a parasitic capacitance between a word line (gate) and a bit line may be minimized.

After forming a first gate conductive layer, the method further comprises depositing a hard mask nitride film over the first gate conductive layer by a Plasma Enhanced-Chemical Vapor Deposition (PE-CVD) or Low Pressure-Chemical Vapor Deposition (LP-CVD) process. The hard mask nitride film may be used as an etch barrier film.

After forming a buried-type gate, the method further comprises performing a Chemical Mechanical Polishing (CMP) process with the hard mask nitride film as an etch barrier film in the cell region and the peripheral circuit region.

Before performing a CMP process, the method further comprises: depositing a polysilicon layer in the semiconductor substrate; performing a CMP process to remove the polysilicon layer with a slurry for selectively etching the polysilicon layer; and performing a CMP process to remove the hard mask oxide film with a slurry for selectively etching the hard mask oxide film.

The method further comprises removing the hard mask nitride film by a wet etching process using a H₃PO₄ etch solution or a dry etching process using an etching selectivity difference between an oxide film and a polysilicon layer.

The step of forming a bit line contact in the cell region includes: etching a gap between the two buried-type gates of the active region in the cell region to form a bit line contact hole; and depositing a conductive layer in the bit line contact hole. The bit line contact and the bit line are simultaneously formed.

The bit line contact hole is formed to have a circular, oval or straight line shape.

After forming a bit line contact hole, the method further comprises forming a spacer including nitride film at sidewalls of the bit line contact hole so as to protect the sidewalls of the bit line contact hole.

After forming a bit line contact, a bit line conductive layer and a second gate conductive layer, the method further comprises: depositing a barrier metal layer, a conductive layer and a hard mask layer over the bit line conductive layer and a second gate conductive layer; and etching the hard mask layer, the conductive layer, the barrier metal layer, the bit line conductive layer and the second gate conductive layer to form a bit line structure of the cell region simultaneously with a gate structure of the peripheral circuit region. The cell bit line and the peripheral circuit gate are simultaneously formed to have the same structure, thereby simplifying the manufacturing process.

After forming a bit line structure and a gate structure, the method further comprises: forming a spacer at sidewalls of the bit line structure and the gate structure; forming a source and a drain in the active region disposed at sidewalls of the gate structure of the peripheral circuit region; and forming a storage node contact and a storage electrode over the active region of the cell region.

### BRIEF DESCRIPTION OF THE DRAWINGS

FIGS. 1 to 8 are diagrams illustrating a method for fabricating a semiconductor device.

### DESCRIPTION OF EMBODIMENTS

Exemplary embodiments of the present invention will be described in detail with reference to the attached drawings.

FIGS. 1 to 8 are diagrams illustrating a method for fabricating a semiconductor device.

Referring to FIG. 1, a device isolation film 14 that defines an active region 12 is formed in a semiconductor substrate including a cell region and a peripheral region, which is also referred to as a peripheral circuit region. The surface of the device isolation film 14 is not even with but formed to protrude higher than the surface of the active region 12. To form this structure having the surface of the device isolation film 14 higher than the surface of the active region 12, the semiconductor substrate is etched with a mask (not shown) having a given thickness and exposing the device isolation film 14 to form a trench 15. Then, a device isolation material such as an oxide film is buried in the trench 15 exposed by the mask (not shown), and, when the mask is removed, the device isolation film 14 is formed to protrude out of the surface of the active region 12 such that the surface of the device isolation film 14 is higher than the surface of the active region 12 by the thickness of the mask (not shown).

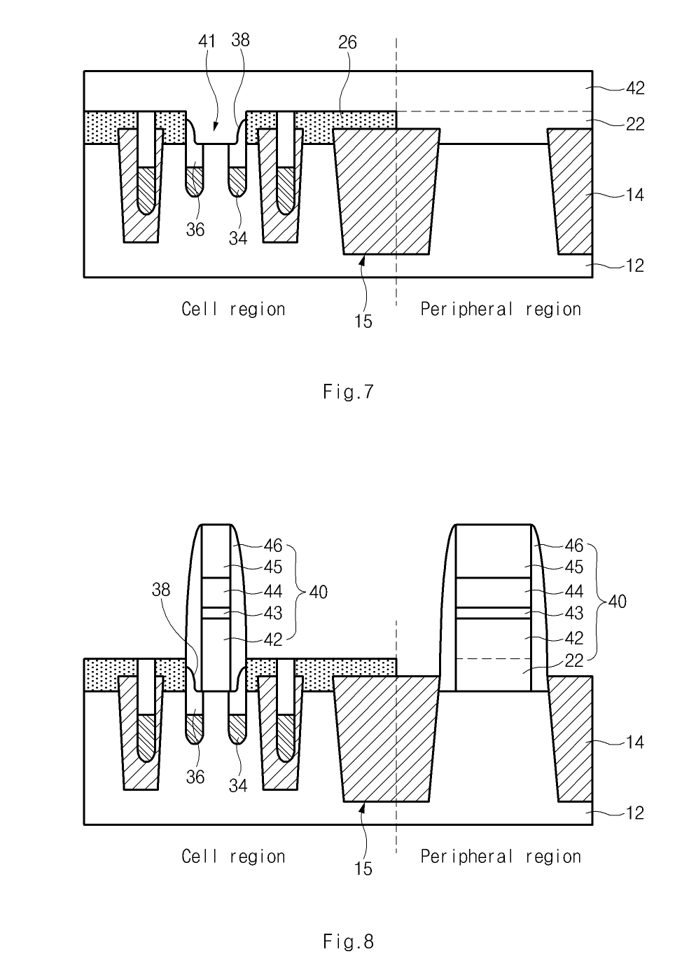

Prior to forming a peripheral circuit gate in the peripheral circuit region, an ion-implanting process and a gate oxide film (not shown) forming process are performed. Referring to FIG. 1, a first gate conductive layer 22 is deposited in the cell region and the peripheral circuit region. The first gate conductive layer 22 in the cell region is removed in a later performed process, but the first gate conductive layer 22 in the peripheral circuit region serves to form a portion of the gate to be formed later. The first gate conductive layer 22 may comprise polysilicon. When forming the first gate conductive layer 22 (as in FIG. 1), the thickness and/or the ion-implanting concentration of the first gate conductive layer 22, which may comprise polysilicon, is set in consideration of a thickness and/or an ion-implanting concentration of a second gate conductive layer 42 that is formed later over the first gate conductive layer 22 (which is described more below with respect to FIG. 7).

A hard mask nitride film 24 having a predetermined thickness is then deposited over the first gate conductive layer 22. The process for depositing the hard mask nitride film 24 may be performed by utilizing a Plasma Enhanced-Chemical Vapor Deposition (PE-CVD) or Low Pressure-Chemical Vapor Deposition (LP-CVD) process. The hard mask nitride film 24 is formed to serve as an etch barrier film in a subsequent Chemical Mechanical Polishing (CMP) process.

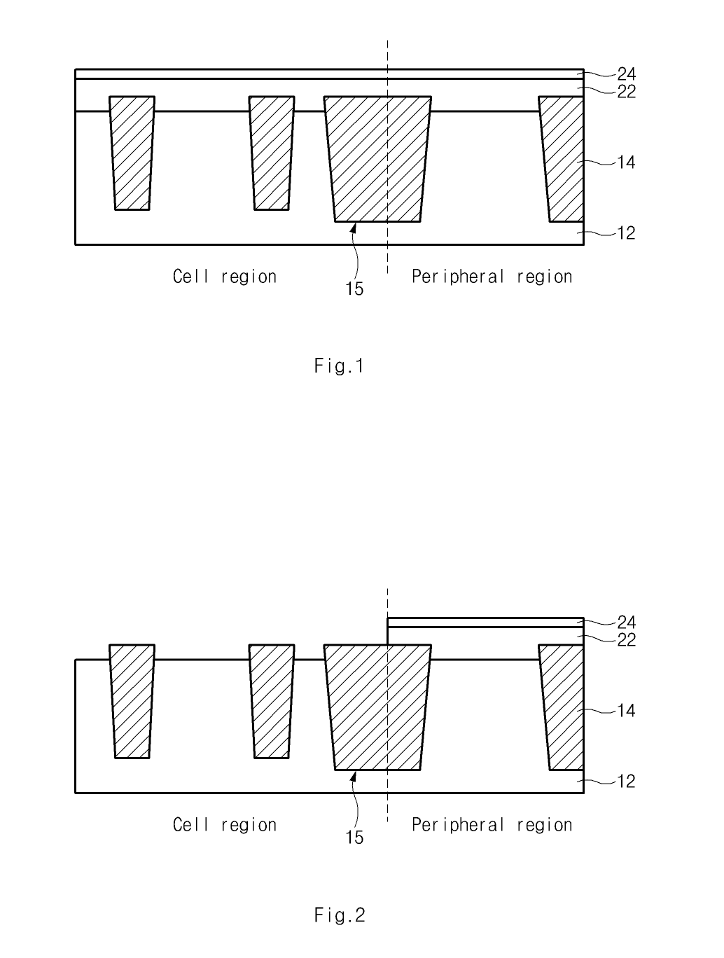

Referring to FIG. 2, a mask (not shown) is formed over the hard mask nitride film 24 to expose the cell region, and the hard mask nitride film 24 and the first gate conductive layer 22 over the cell region are etched so as to expose the active region 12 and the device isolation film 14 in the cell region. The process for etching the hard mask nitride film 24 and the first gate conductive layer 22 in the cell region may be performed by a dry etch process. The process for etching the first gate conductive layer 22 comprising polysilicon is finished with an oxide film (not shown) formed over the active region 12 using an etching condition of increasing an etching selectivity with the oxide film (not shown). A well ion-implanting process and a channel ion-implanting process are performed on the cell region.

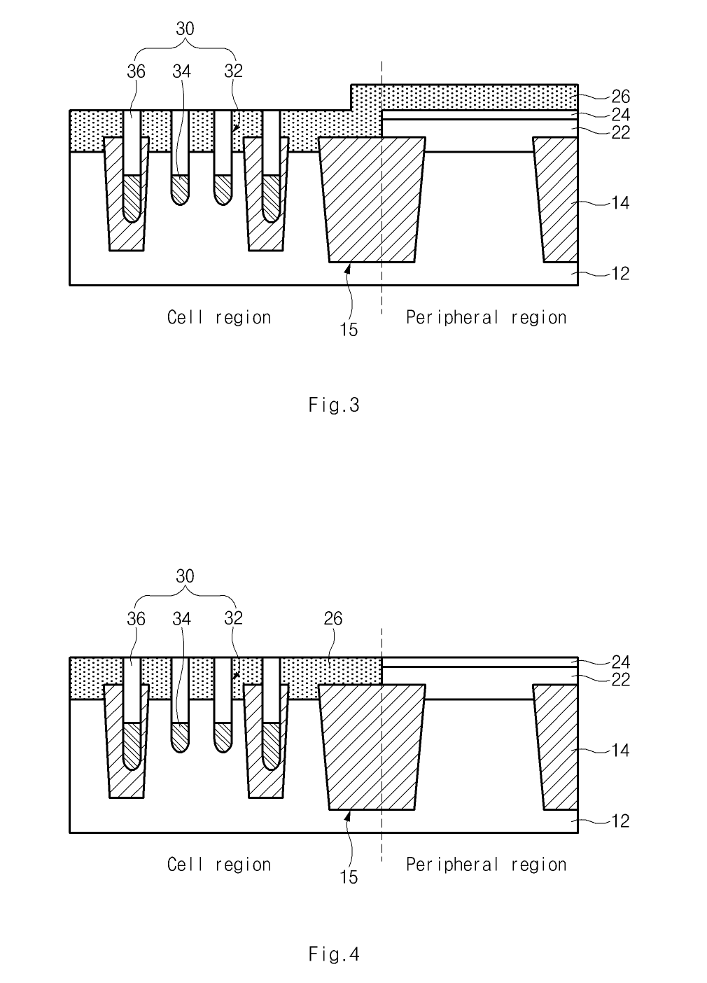

Referring to FIG. 3, a hard mask oxide film 26 having a predetermined thickness is deposited by a LP-CVD process to form a buried-type gate. Selected portions of the active region 12 and the device isolation film 14 in the cell region are etched to predetermined depths (which could be same or different) to form recesses 32 for forming a buried-type gate. A gate oxide film is formed on the surface of each recess 32, and then material for a gate electrode 34 is deposited in each recess 32. The material for a gate electrode 34 may include a titanium nitride (TiN) film or a stacked structure including a titanium nitride (TiN) film and tungsten (W). The upper portion of the gate electrode 34 material is planarized by a CMP process. An etch-back process is performed to remove the gate electrode 34 in each recess 32 such to a predetermined depth from the surface of the active region 12.

A capping nitride film 36 is deposited over the gate electrode 34 in each recess 32 in the cell region, and the excess capping nitride film 36 disposed over the recesses 32 is removed by a wet etching process using an etch solution such as H₃PO₄ or a dry etching process using an increased etching selectivity between the nitride film and the oxide film. As a result, the surface of the hard mask oxide film 26 is exposed to form a buried-type gate 30 comprising the gate electrode 34 and the capping nitride film 36 in each recess 32.

Referring to FIG. 4, a CMP process is performed on the cell region and the peripheral circuit region to planarize the surface of the cell region and the peripheral circuit region. Specifically, the CMP process is performed with the hard mask nitride film 24 of the peripheral circuit region as an etch barrier film to remove the hard mask oxide film 26. Prior to performing the CMP process, a polysilicon layer is deposited to a predetermined thickness in the semiconductor substrate having the cell region and the peripheral circuit region. The polysilicon layer is then removed by a CMP process using a slurry by selectively etching the polysilicon layer. The hard mask oxide film 26 is removed by a CMP process using a slurry by selectively etching the hard mask oxide film 26.

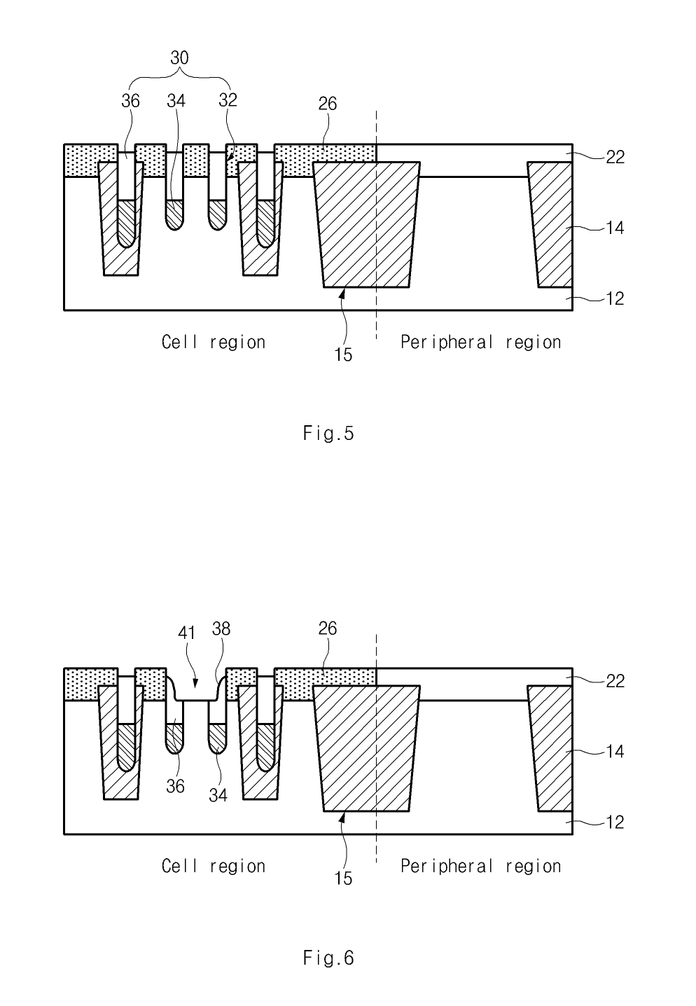

Referring to FIG. 5, the hard mask nitride film 24 in the peripheral circuit region is removed by a wet etching process using an etch solution such as H₃PO₄ or a dry etching process using an etching selectivity difference between the oxide film 24 and the polysilicon 22. The capping nitride film 36 in each recess 32 in the cell region is etched to expose a predetermined depth in each recess 32.

Referring to FIG. 6, the capping nitride film 36 and the hard mask oxide film 26 in the bit line contact region, which corresponds to a gap between the two outer-end buried-type gates 30 in the cell region of the active region 12, are etched to form a bit line contact hole 41. The bit line contact hole 41 may be formed to have one of various cross-sectional profiles including a circular or oval shape or a straight line type. In order to protect the sidewalls of the bit line contact hole 41, a spacer 38 including a nitride film may be additionally formed at the sidewalls of the bit line contact hole 41.

Referring to FIG. 7, a second gate conductive layer 42 is deposited in the cell region and the peripheral circuit region. The second gate conductive layer 42 may include polysilicon. The deposited second gate conductive layer 42 is used in forming a portion of a conductive layer of a gate in the peripheral circuit region and in forming a conductive layer and a bit line contact plug of the bit line in the cell region. When forming the second gate conductive layer 42, the thickness and/or the ion-implanting concentration of the second gate conductive layer 42, which may include polysilicon, are set in consideration of the thickness and/or the ion-implanting concentration of the first gate conductive layer 22 formed below the second gate conductive layer 42 in the peripheral circuit region. Before depositing a second gate conductive layer 42, a wet etching process may be performed to remove the oxide film that may remain over the first gate conductive layer 22 in the peripheral circuit region and the bottom surface of the bit line contact hole 41 in the cell region.

Referring to FIG. 8, a barrier metal layer 43, a conductive layer 44, and a hard mask layer 45 are sequentially deposited over the second gate conductive layer 42. Then, the hard mask layer 45, the conductive layer 44, the barrier metal layer 43, and the second gate conductive layer 42 are sequentially etched with an additional mask (not shown) to form a bit line structure 40 in the cell region and a gate structure 40 in the peripheral circuit region. A spacer 46 including a nitride film is formed on the sidewalls of the gate structure 40 in the peripheral circuit region and the bit line structure 40 in the cell region so as to protect the sidewalls of each structure.

The process of etching the second gate conductive layer 42, which may include polysilicon, is performed under having a sufficient etching selectivity with a gate oxide film (not shown) disposed in the lower portion of the second gate conductive layer 42. After forming the structure as shown in FIG. 8, a source and a drain are formed by an ion-implanting process, and a storage node contact and a storage electrode are formed, thereby completing the processes for forming a semiconductor device.

As described above, the method according to an embodiment of the present invention minimizes a process for opening the cell region and the peripheral circuit region, thereby minimizing the defects that can be generated in the boundary between the cell region and the peripheral circuit region.

The above embodiments of the present invention are illustrative and not to limit the scope of the present invention. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for fabricating a semiconductor device having a semiconductor substrate including a cell region and a peripheral circuit region, the method comprising:
forming a first gate conductive layer in the peripheral circuit region;
forming a buried-type gate in the cell region;
forming a bit line contact and a bit line conductive layer in the cell region; and
forming a second gate conductive layer in the peripheral circuit to region.

2. The method according to claim 1, wherein the step of forming a bit line contact and a bit line conductive layer in the cell region and the step of forming a second gate conductive layer in the peripheral circuit region are performed simultaneously.

3. The method according to claim 1, further comprising:
forming a mask that exposes one or more device isolation regions in each of the cell region and the peripheral circuit region;
etching the semiconductor substrate with the mask to form a trench;
depositing a device isolation material in the trench; and
removing the mask.

4. The method according to claim 1, wherein the step of forming a buried type gate in the cell region comprises:
depositing a hard mask oxide film in the cell region;
forming one or more recesses in the cell region by etching an active region and a device isolation film in the cell region with the hard mask oxide film as a mask;
depositing a gate electrode in a lower portion of each recess; and
depositing a capping nitride film over the gate electrode in each recess.

5. The method according to claim 4, further comprising depositing a hard mask nitride film over the first gate conductive layer by a Plasma Enhanced-Chemical Vapor Deposition (PE-CVD) or Low Pressure-Chemical Vapor Deposition (LP-CVD) process.

6. The method according to claim 5, further comprising performing a Chemical Mechanical Polishing (CMP) process with the hard mask nitride film as an etch barrier film in the cell region and the peripheral circuit region.

7. The method according to claim 6, further comprising:
depositing a polysilicon layer in the semiconductor substrate;
performing a CMP process to remove the polysilicon layer with a slurry for selectively etching the polysilicon layer; and
performing a CMP process to remove the hard mask oxide film with a slurry for selectively etching the hard mask oxide film.

8. The method according to claim 6, further comprising removing the hard mask nitride film by a wet etching process using a H₃PO₄ etch solution or a dry etching process using an etching selectivity difference between an oxide film and a polysilicon layer.

9. The method according to claim 1, wherein the step of forming a bit line contact in the cell region comprises:
etching a predetermined region in the active region of the cell region to form a bit line contact hole; and
depositing a conductive layer in the bit line contact hole.

10. The method according to claim 9, wherein the bit line contact hole is formed to have a circular, oval, or straight line shape.

11. The method according to claim 9, further comprising forming a spacer including nitride film at sidewalls of the bit line contact hole.

12. The method according to claim 1, further comprising:
depositing a barrier metal layer, a conductive layer, and a hard mask layer over the bit line conductive layer and a second gate conductive layer; and
simultaneously forming a bit line structure in the cell region and a gate structure in the peripheral circuit region by etching the hard mask layer, the conductive layer, the barrier metal layer, the bit line conductive layer, and the second gate conductive layer.

13. The method according to claim 12, further comprising:
forming a spacer at sidewalls of the bit line structure and the gate structure;
forming a source and a drain in the active region disposed at sidewalls of the gate structure of the peripheral circuit region; and
forming a storage node contact and a storage electrode over the active region of the cell region.
